(19) United States
(12) Patent Application Publication
(10) Pub. No.: US 2024/0107705 A1
(43) Pub. Date: Mar. 28, 2024

(54) ASSEMBLED COLD PLATE FOR COMPUTE BLADE

(71) Applicants: BULL SAS, Les Clayes-sous-Bois (FR); Le Commissariat à l’énergie atomique et aux énergies alternatives (CEA), Paris (FR)

(72) Inventors: Marc RAETH, Tacoignières (FR); Fabien DEMANGE, Achères (FR)

(73) Assignees: BULL SAS, Les Clayes-sous-Bois (FR); Le Commissariat à l’énergie atomique et aux énergies alternatives (CEA), Paris (FR)

(21) Appl. No.: 18/469,950

(22) Filed: Sep. 19, 2023

(30) Foreign Application Priority Data
Sep. 28, 2022 (EP) 22306440.3

(51) Int. Cl. H05K 7/20

(52) U.S. Cl. CPC H05K 7/20254; H05K 7/20772

(57) ABSTRACT

Cold plate for a supercomputer compute blade, said cold plate delimiting at least one opening configured to receive at least one heat sink configured to cool at least one electronic component, said cold plate comprising a cooling circuit, comprising channels within which is configured to circulate a “cold” heat transfer fluid to supply said at least one heat sink, and a discharge circuit, comprising channels within which a “hot” heat transfer fluid is configured to circulate after heating through the at least one heat sink, said cold plate consists of an assembly of several separate elements, wherein each pair of adjacent elements fluidly connected at a portion of the cooling circuit or of the discharge circuit comprises a sealing member at the interface of said connection.

This application claims priority to European Patent Application Number 22306440.3, filed 28 Sep. 2022, the specification of which is hereby incorporated herein by reference.

### BACKGROUND OF THE INVENTION

### Technical Field of the Invention

At least one embodiment of the invention relates to the field of supercomputers and relates more particularly to a cold plate for a compute blade of a supercomputer.

### Description of the Related Art

A HPC (High Performance Computing) computer, or supercomputer, comprises a plurality of compute blades in the form of modules inserted into a bay. Each compute blade comprises a motherboard comprising a plurality of processors each configured to process data.

In liquid-cooled HPC computers, the motherboard is mounted under a so-called “cold” plate, through which heat sinks making it possible to cool the processors are mounted. The cold plate comprises a cooling circuit, allowing a heat transfer fluid to be conveyed to the inlet of the heat sinks, and a discharge circuit, enabling the heated heat transfer fluid exiting from the heat sinks outside the cold plate to be conveyed into an external fluid cooling unit, for example of the water-water heat exchanger type, for the purpose of transferring heat, for example to a domestic water network.

The main aluminum cold plate solution is currently not widely used and systems that capture all the calories dissipated in the compute blade in the hydraulic network are rare. Another type of solution uses independent heat sinks and is therefore not concerned by the problem presented here.

Some solutions use copper parts interconnected via flexible pipes.

Finally, other solutions use single or two-phase immersion cooling techniques where servers are directly immersed in a dielectric fluid.

One-piece cold plates are used in the automotive or aeronautics sector with large-dimension aluminum exchangers, often brazed and heavily tooled.

Historically, the first cold plaques made by the Applicant were made from a single one-piece part. As the dimensions were relatively small, the dimensional manufacturability constraint had little impact and the sealing reliability was promoted with a single aluminum block wherein the waterway passed.

However, the known single-piece cold plates have several disadvantages. For large parts, this solution is not compatible with the size of the friction-stir machines used for their manufacture. In addition, on these parts with relatively substantial dimensions (diagonal around 800 mm), obtaining good final flatness around 0.1 mm is very difficult to obtain. The heating of the parts during the friction-stir process creates deformations which are very difficult to check on such large parts.

As soon as the system has internal openings, the loss of material generated by the one-piece solution makes this solution uncompetitive economically (material cost and extended machining time).

The design is unique by definition and must therefore be completely modified in the event of a problem and is very difficult to reuse as soon as the geometry of the object to be cooled changes.

There is therefore a need for a simple and effective solution to overcome at least some of these disadvantages.

### BRIEF SUMMARY OF THE INVENTION

To this end, at least one embodiment of the invention is firstly a cold plate for a supercomputer compute blade, the cold plate delimiting at least one opening configured to receive at least one heat sink intended to cool at least one electronic component, the cold plate comprising a cooling circuit, comprising channels within which is intended to circulate a “cold” heat transfer fluid to supply said at least one heat sink, and a discharge circuit, comprising channels within which a “hot” heat transfer fluid is intended to circulate after heating through the at least one heat sink, the cold plate being remarkable in that it consists of (or is constituted of) an assembly of several separate elements wherein each pair of adjacent elements fluidly connected at a portion of the cooling circuit or of the discharge circuit comprises a sealing member at the interface of said connection.

The cold plate according to one or more embodiments of the invention makes it possible to avoid having to machine material to form the openings into which the heat sinks will be arranged, unlike a one-piece plate which must undergo machining to form the openings. The material saved in this way reduces the cost of the plate. Next, using several elements makes it possible to adapt the cold plate to different shapes and types of heat sinks and compute blades. In addition, in at least one embodiment, small-size elements are easier to manufacture and result in less deformation of the cold plate. Furthermore, in at least one embodiment, certain elements may be reused from one type of cold plate to another or within the same cold plate in order to facilitate the manufacture of parts and reduce the costs of the cold plate. Similarly, in at least one embodiment, an element may easily be replaced without having to change the entire cold plate. With several elements, it is possible to choose different materials and manufacturing processes, in particular for elements that are not in contact with the refrigerant. The way parts are cut and assembled together is untrivial because it requires calculations of mechanical stiffness and percentage loss of material during machining phases.

Advantageously, in at least one embodiment, the general shape of the cold plate is defined for the exterior according to the interfaces of the computer cabinet and for the interior according to the location of the dissipative elements to be cooled.

The cutting of parts is carried out in order to allow for the best compromise between optimizations of material lost during manufacture, rigidity and mechanical assembly tolerances of the finished assembly, as well as limiting the number of hydraulic interfaces with seals.

Some elements are used for circulating the heat transfer fluid and must follow the rules of aluminum mixing-stir manufacturing, others are pure machined parts the materials of which may be adapted if necessary.

Preferably, in at least one embodiment, the sealing member is of the O-ring type.

Advantageously, in one or more embodiments, the elements of the cold plate are fastened together two by two by fastening members, preferably of the fastening screw type.

According to at least one embodiment of the invention, at least one pair of elements of the cold plate comprises positioning members.

Preferably, in at least one embodiment, each pair of adjacent elements of the cold plate comprises positioning members at their connection.

Advantageously, in one or more embodiments, the positioning members comprise at least one indexing pin inserted into a complementary shape, for example a cavity, in order to perfectly position the two elements during their assembly, in particular in order to ensure that the sealing members are positioned correctly for perfect sealing of the cold plate.

Preferably, in at least one embodiment, the indexing pins and complementary shapes are provided with tight tolerances, which in particular makes it possible to guarantee good relative positions before tightening the fastening screws.

According to at least one embodiment of the invention, the elements are made of metal, preferably aluminum.

At least one embodiment of the invention also relates to a method for assembling a cold plate such as presented previously, said method comprising a step for positioning the elements together and a step for fastening the elements together so as to form the cooling circuit and the discharge circuit, the positioning of the elements together comprising the placement of a sealing member at each fluidic connection interface of a portion of the cooling circuit and/or of the discharge circuit of adjacent elements.

Advantageously, in at least one embodiment, the elements may be fastened in pairs.

Preferably, in one or more embodiments, the fastening is made by interlocking or screwing.

Further advantageously, in at least one embodiment, the positioning of the elements together comprises guiding the elements by positioning members.

### BRIEF DESCRIPTION OF THE DRAWINGS

Further characteristics and advantages of the one or more embodiments of the invention will further appear upon reading the description that follows. This is purely illustrative and should be read in conjunction with the appended drawings in which:

FIG. 1 schematically shows a cold plate according to one or more embodiments of the invention, in exploded view.

FIG. 2 schematically shows the cold plate of FIG. 1 assembled, according to one or more embodiments of the invention.

FIG. 3 schematically shows a view of the junction, in particular the fluidic connection, between the proximal edge and the central part of the cold plate of FIG. 1, according to one or more embodiments of the invention.

FIG. 4 schematically shows in exploded view the positioning members located at the junction between the proximal edge and the junction member of the cold plate of FIG. 1, according to one or more embodiments of the invention.

FIG. 5 schematically shows an embodiment of the method according to one or more embodiments of the invention.

### DETAILED DESCRIPTION

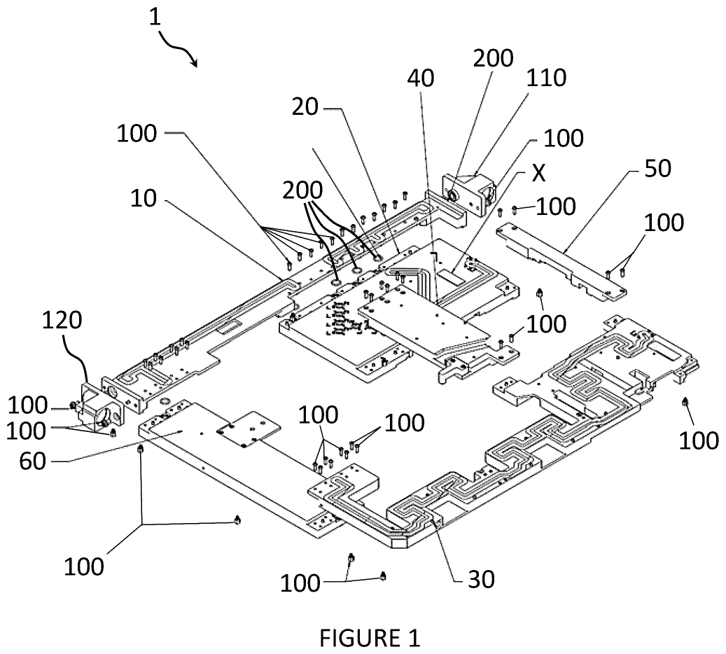

FIG. 1 shows an example of elements of a cold plate 1 before assembly, according to one or more embodiments of the invention.

The cold plate 1 according to at least one embodiment of the invention is intended to be mounted in a compute blade of a supercomputer (not shown). Such a compute blade comprises electronic components, in particular of the processor type, making it possible to process data in a computerized manner.

The purpose of the cold plate 1 is in particular to constitute a circulation circuit of a refrigerant wherein one or more heat sinks are placed making it possible to cool the processors and other electronic components of the compute blade. The refrigerant circulation circuit comprises an upstream part, called a “cooling circuit”, the role of which is to route the “cold” refrigerant to the inlet of the heat sinks, and a downstream part, called a “discharge circuit”, the role of which is to convey the “hot” (or “heated”) refrigerant, i.e. which has collected calories produced by the processors and other electronic components (i.e. the heat emitted), outside the cold plate 1, for example to a cooling unit for the coolant arranged outside the compute blade. Such a cooling unit may be a water/water plate heat exchanger type. In this exchanger, on one side, the “heated/hot” refrigerant fluid circulates, and on the other, the water network of the customer that recovers the calories from the previous network.

According to at least one embodiment of the invention, the cold plate 1 is made by mechanical assembly of a plurality of elements.

In the example shown in FIG. 1, according to one or more embodiments of the invention, the cold plate 1 first comprises a streamlined proximal edge 10 the function of which is to allow the inflow and outflow of the refrigerant from the cold plate 1. In other words, in at least one embodiment, the proximal edge 10 is the start of the cooling circuit and the end of the discharge circuit.

For this purpose, by way of at least one embodiment, the proximal edge 10 comprises at one of its ends a refrigerant inlet connector 110 and at the other end a refrigerant outlet connector 120. The inlet connector 110 and the outlet connector 120 are mounted on the proximal edge 10 using screws 100.

The inlet connector 110 and the outlet connector 120 are each configured to receive a tube, for example flexible, allowing the cold plate 1 to be connected to the cooling module of the cooling fluid, in particular when the cold plate 1 is mounted in the compute blade.

Still in the example shown in FIG. 1, according to one or more embodiments of the invention, the proximal edge 10 is mounted on a substantially rectangular central part 20 making it possible to convey the fluid to the heat sinks. The proximal edge 10 and the central part 20 are assembled using screws 100.

The cold plate 1 then comprises a distal edge 30 connected to the central part 20 by a first connection member 40 and by a second connection member 50.

The distal edge 30 comprises a part of the discharge circuit.

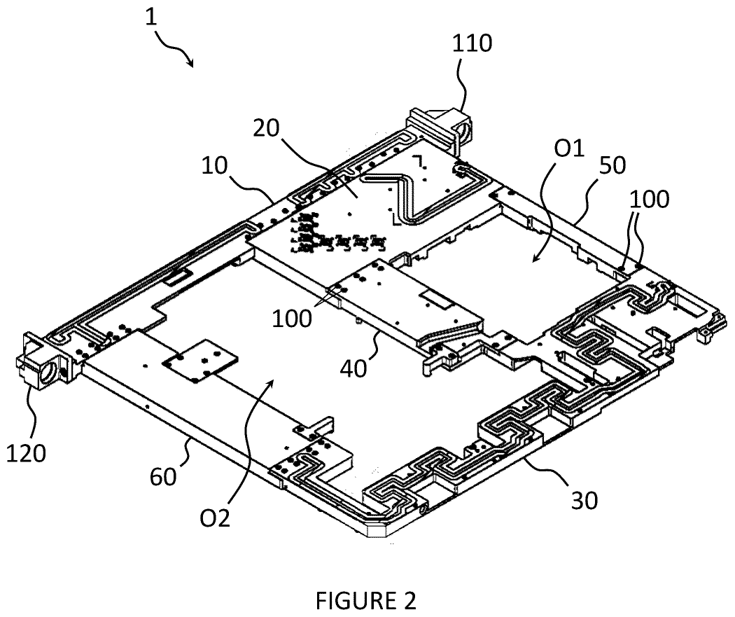

In reference to FIG. 2, according to one or more embodiments of the invention, the central part 20, the distal edge 30, the first connection member 40, and the second connection member 50, when assembled, delimit a first opening O1 for receiving a heat sink (not shown for clarity) which is configured to connect on the one hand to the cooling circuit at the central part 20 to receive the cold refrigerant and on the other hand to the discharge circuit of the distal edge 30 to discharge the heated refrigerant to the outlet connector 120.

In order to convey the heated coolant from the distal edge 30 to the proximal edge 10, in at least one embodiment, the cold plate 1 comprises a fluidic junction member 60 mounted between the proximal edge 10 and the distal edge 30. In other words, in at least one embodiment, the fluidic junction member 60 is part of the discharge circuit and allows the heated coolant to be conveyed from the distal edge 30 to the proximal edge 10 which then leads it to the outlet connector 120.

Still in reference to FIG. 2, according to one or more embodiments of the invention, the proximal edge 10, the central part 20, the distal edge 30, the first connection member 40, and the junction member 60, when assembled, delimit a second opening O2 for receiving two pairs of heat sinks (not shown for clarity) which are each configured to connect on the one hand to the cooling circuit at the central part 20 to receive the cold refrigerant and on the other hand to the discharge circuit of the distal edge 30 and to the junction member 60 to discharge the heated refrigerant to the outlet connector 120.

As the cooling circuit and the discharge circuit are made of separate elements, sealing members are used at the fluidic connections between the different elements.

In FIG. 1, according to one or more embodiments of the invention, the sealing members are in the form of O-rings 200 placed at the interface of each fluidic connection between two elements. In FIG. 1, in at least one embodiment, only the O-rings 200 placed at the fluidic connections between the proximal edge 10 and the central part 20 and the O-ring placed between the inlet connector 110 and the proximal edge 10 were shown for the sake of clarity, but it goes without saying that the assembly of the fluidic connections between the elements of the cold plate 1 are provided with such O-rings 200 to ensure the seal of the coolant circulation circuit in said cold plate 1.

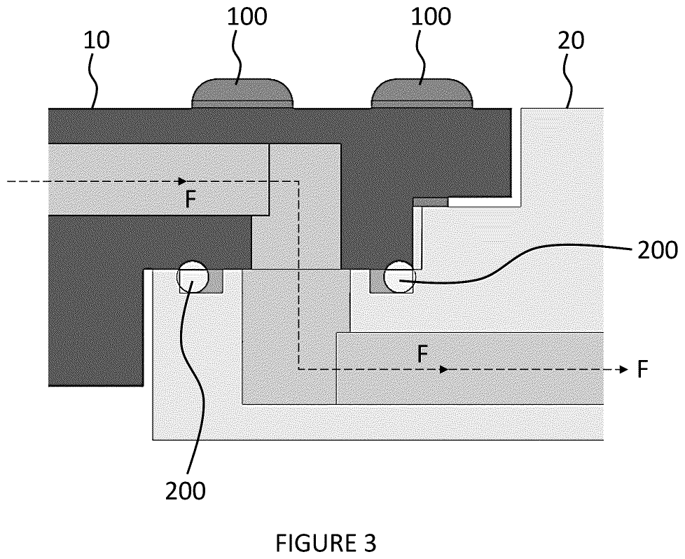

In reference to FIG. 3, according to one or more embodiments of the invention, in which a fluidic connection interface has been shown between the proximal edge 10 and the central part 20, the O-ring 200 is placed in a groove formed, in this non-limiting example, in the central part 20 so as to be in controlled compression around the fluidic connection between the proximal edge 10 and the central part 20. Thus, in at least one embodiment, the flow F of the coolant may travel from the proximal edge 10 to the central part 20 without loss. As indicated above, sealing members, notably of the O-ring 200 type, may be used where necessary at the interface of the fluidic connections in the refrigerant circulation circuit (cooling circuit and discharge circuit).

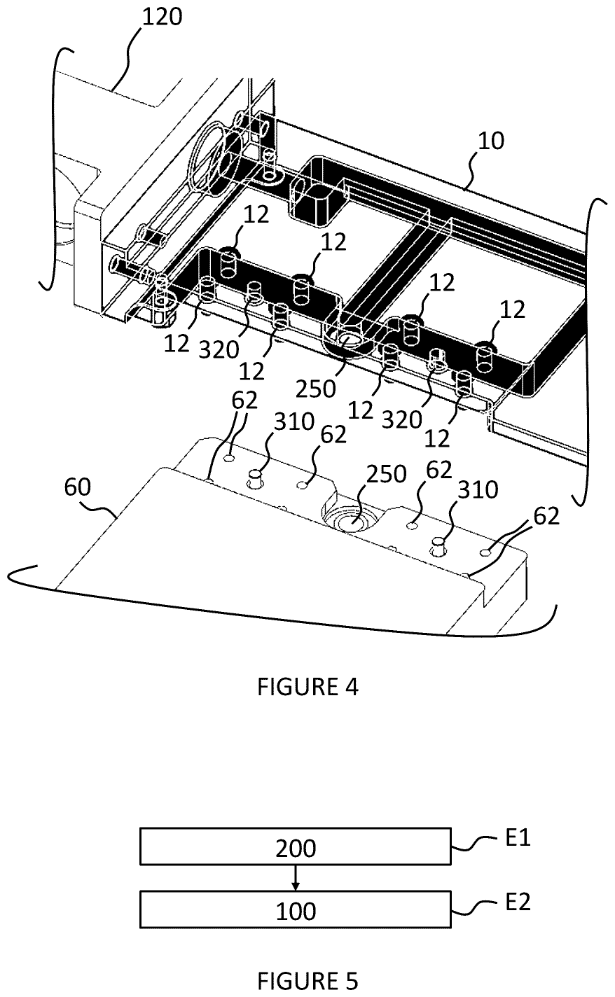

In reference to FIG. 4, according to one or more embodiments of the invention, where the junction between the proximal edge 10 and the junction member 60 is shown, positioning members are used to facilitate the assembly of the elements and to ensure the proper alignment of the orifices 250 of the evacuation circuit.

These positioning members in particular comprise indexing pins 310 adapted to fit in complementary locking cavities 320, preferably with tight tolerances (i.e. less than or of about a millimeter). In the example of FIG. 4, in at least one embodiment, the junction member 60 comprises two indexing pins 310, arranged symmetrically on either side of the fluidic connection of the discharge circuit and the proximal edge 10 comprises two locking cavities 320.

FIG. 4 also shows the screw receiving orifices 100 at both the proximal edge 10 (orifices 12) and the junction member (orifices 62).

Assembling the Cold Plate

First, by way of at least one embodiment, in a step E1, O-rings 200 are placed around the fluidic junctions of the refrigerant circulation circuit of the cold plate 1 at the interface of the elements of the cold plate 1 concerned by said circulation circuit.

The elements are assembled two by two by tightening the screws 100 in the corresponding orifices 12, 62 in step E2. When tightening the screws 100, the O-rings 200 are compressed under controlled compression up to the stop of the elements of the cold plate 1 so as to guarantee the seal of the fluidic connections.

The cold plate 1 according to one or more embodiments of the invention makes it possible, thanks to an assembly of elements, to adapt to any type and form of heat sink while saving the volume of material of the openings that were otherwise machined and therefore removed. The sealing devices make it possible to guarantee the sealing of the coolant circulation circuit and thus the efficiency of the cold plate 1.

1. A cold plate for a supercomputer compute blade, said cold plate delimiting at least one opening configured to receive at least one heat sink intended to cool at least one electronic component, said cold plate comprising:
a cooling circuit comprising channels, wherein said cooling circuit is configured to circulate a cold heat transfer fluid within said channels to supply said at least one heat sink, and
a discharge circuit comprising channels, wherein said discharge circuit is configured to circulate a hot heat transfer fluid within said channels of said discharge circuit after heating through the at least one heat sink,
wherein said cold plate comprises an assembly of several separate elements, wherein each pair of adjacent elements of said several separate elements that are fluidly connected via a connection at a portion of the cooling circuit or of the discharge circuit comprises a sealing member at an interface of said connection.

2. The cold plate according to claim 1, wherein the sealing member is an O-ring.

3. The cold plate according to claim 1, wherein the several separate elements of the cold plate are fastened together in pairs by fastening members.

4. The cold plate according to claim 3, wherein the fastening members comprise fastening screws.

5. The cold plate according to claim 1, wherein at least one pair of elements of said each pair of adjacent elements of the cold plate comprises positioning members.

6. The cold plate according to claim 5, wherein the positioning members comprise at least one indexing pin inserted into a complementary shape.

7. The cold plate according to claim 1, wherein the several separate elements are made of metal.

8. A method for assembling a cold plate for a supercomputer compute blade, said cold plate delimiting at least one opening configured to receive at least one heat sink intended to cool at least one electronic component, said cold plate comprising,
a cooling circuit comprising channels, wherein said cooling circuit is configured to circulate a cold heat transfer fluid within said channels to supply said at least one heat sink, and
a discharge circuit comprising channels, wherein said discharge circuit is configured to circulate a hot heat transfer fluid within said channels of said discharge circuit after heating through the at least one heat sink,
wherein said cold plate comprises an assembly of several separate elements, wherein each pair of adjacent elements of said several separate elements that are fluidly connected via a connection at a portion of the cooling circuit or of the discharge circuit comprises a sealing member at an interface of said connection;
said method comprising:
positioning the several separate elements together, and
fastening the several separate elements together to form the cooling circuit and the discharge circuit,
wherein the positioning of the several separate elements together comprises placing said sealing member at each fluidic connection interface said portion of the cooling circuit or of the discharge circuit of said each pair of adjacent elements.

9. The method according to claim 8, wherein the fastening is done by interlocking or screwing.

10. The method according to claim 8, wherein the positioning of the several separate elements together comprises guiding at least part of the several separate elements by positioning members.
